(19) United States
(12) Patent Application Publication
(10) Pub. No.: US 2022/0238414 A1
(43) Pub. Date: Jul. 28, 2022

(54) THERMAL CONDUCTIVE STRUCTURE AND ELECTRONIC DEVICE

(71) Applicant: CTRON Advanced Material Co., Ltd, Xinxiang City (CN)

(72) Inventors: Ming-Hsiang He, Xinxiang City (CN); Chun-Kai Huang, Xinxiang City (CN); Han-Chang Huang, Xinxiang City (CN)

(21) Appl. No.: 17/541,782

(22) Filed: Dec. 3, 2021

(30) Foreign Application Priority Data
Jan. 27, 2021 (TW) 110103093

(51) Int. Cl. H01L 23/373

(52) U.S. Cl. CPC H01L 23/3737; H01L 23/3735; H01L 23/3731; H01L 23/3736

(57) ABSTRACT

A thermal conductive structure and an electronic device are provided. The thermal conductive structure includes a thermal conductive metal layer and a structural layer. The structural layer is disposed on the thermal conductive metal layer. The structural layer is a stacked structure formed by a graphene layer and a ceramic material layer, or the structural layer is a graphene-mixed ceramic material layer. The thermal conductive structure can quickly conduct the heat energy generated by the heat source to the outside, thereby improving the heat dissipation performance of the electronic device.

### CROSS REFERENCE TO RELATED APPLICATIONS

This Non-provisional application claims priority under 35 U.S.C. § 119(a) on Patent Application No(s). 110103093 filed in Taiwan, Republic of China on Jan. 27, 2021, the entire contents of which are hereby incorporated by reference.

### BACKGROUND

### Technology Field

The present disclosure relates to a thermal conductive structure and, in particular, to a thermal conductive structure and an electronic device capable of improving heat dissipation performance.

### Description of Related Art

With the development of technology, the thin structure and high performance are the priority considerations for the design and development of electronic devices. Under the high-speed operation and thin structure requirements, the electronic components of electronic device will inevitably generate more heat than ever. Therefore, the “heat dissipation” has become an indispensable function of these components or devices. Especially for high-power components, the temperature of electronic products will rise rapidly due to the substantial increase in heat generated during operation. When the electronic product is exposed to an excessive temperature, it may cause permanent damage to the components or significantly reduce the lifetime thereof

In most of the conventional arts, the waste heat generated in operation is dissipated by the heat sink, fan, or heat-dissipation element (e.g. heat pipe) installed on the components or devices. In general, the heat sink or the heat-dissipation element generally has a certain thickness, and is made of metal material with high thermal conductivity, or a material doped with an inorganic material with high thermal conductivity. Although the thermal conduction effect of the metal material is very good, but the density thereof is large, resulting in the heavy weight and large thickness of the entire heat sink or heat-dissipation element. In addition, the structural strength of a polymer composite doped with the inorganic material is not good and may not be suitable for some products.

Therefore, it is desired to provide a thermal conductive structure, which is more suitable for high-power component or device, and can be applied to different product fields to meet the requirement of thin design.

### SUMMARY

An objective of this disclosure is to provide a thermal conductive structure and an electronic device with the thermal conductive structure. The thermal conductive structure of this disclosure can rapidly conduct the heat energy generated by the heat source of the electronic device to the outside, thereby improving the heat dissipation performance.

The thermal conductive structure of this disclosure can be applied to different product fields to meet the requirement of thin design.

A thermal conductive structure of this disclosure comprises a thermal conductive metal layer and a structural layer. The structural layer is disposed on the thermal conductive metal layer. The structural layer is a stacked structure formed by a graphene layer and a ceramic material layer; or the structural layer is a graphene-mixed ceramic material layer.

In one embodiment, the thermal conductive metal layer comprises copper, aluminum, copper alloy, or aluminum alloy.

In one embodiment, the material of the ceramic material layer comprises boron nitride, aluminum oxide, aluminum nitride, silicon carbide, or any combination thereof.

In one embodiment, the material of the graphene-mixed ceramic material layer comprises graphene and a ceramic material, and the ceramic material comprises boron nitride, aluminum oxide, aluminum nitride, silicon carbide, or any combination thereof.

In one embodiment, the ceramic material layer is disposed between the graphene layer and the thermal conductive metal layer.

In one embodiment, the graphene layer is disposed between the ceramic material layer and the thermal conductive metal layer.

In one embodiment, a surface of the ceramic material layer away from the thermal conductive metal layer is configured with a plurality of microstructures, and a shape of the microstructures is columnar, spherical, pyramidal, trapezoidal, irregular shape, or any combination thereof.

In one embodiment, the ceramic material layer further comprises a filling material and/or a plurality of pores.

In one embodiment, a surface of the graphene-mixed ceramic material layer away from the thermal conductive metal layer is configured with a plurality of microstructures, and a shape of the microstructures is columnar, spherical, pyramidal, trapezoidal, irregular shape, or any combination thereof.

In one embodiment, the graphene-mixed ceramic material layer further comprises a filling material.

In one embodiment, the filling material comprises aluminum oxide, aluminum nitride, silicon carbide, boron nitride, or any combination thereof.

In one embodiment, the shape of the filling material comprises granular, flake, spherical, strip, nanotube, irregular, or any combination thereof.

In one embodiment, the thermal conductive structure further comprises a double-sided adhesive layer disposed at one side of the thermal conductive metal layer away from the structural layer.

In one embodiment, the double-sided adhesive layer is a thermal conductive double-sided tape.

An electronic device of this disclosure comprises a heat source and a thermal conductive structure as mentioned above, wherein the thermal conductive structure is connected to the heat source.

In one embodiment, the electronic device further comprises a heat-dissipation structure disposed at one side of the thermal conductive structure away from the heat source.

As mentioned above, in the thermal conductive structure of this disclosure, the structural layer is disposed on the thermal conductive metal layer, and the structural layer is a stacked structure formed by a graphene layer and a ceramic material layer, or a graphene-mixed ceramic material layer. When the thermal conductive structure is connected to the heat source of the electronic device, the heat energy generated by the heat source can be rapidly and effectively conducted to the outside, thereby improving the heat dissipation performance of the electronic device. Moreover, the thermal conductive structure of this disclosure can be applied to different product fields, thereby achieving the requirement of thin design of the electronic device. Besides, compared with the conventional protective layer that is made of PI, the ceramic material layer of one embodiment of this disclosure can provide the protection and insulation effects, and can further improve the thermal conductive effect.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a thermal conductive structure according to an embodiment of this disclosure;

FIGS. 2A to 2G are schematic diagrams showing the thermal conductive structures according to different embodiments of this disclosure; and

FIGS. 3 and 4 are schematic diagrams showing the electronic devices according to different embodiments of this disclosure.

### DETAILED DESCRIPTION OF THE DISCLOSURE

The present disclosure will be apparent from the following detailed description, which proceeds with reference to the accompanying drawings, wherein the same references relate to the same elements. The elements appearing in the following embodiments are only used to illustrate the relative relationships thereof, and do not represent the real proportions or sizes thereof.

When the thermal conductive structure of the present disclosure is applied to an electronic device, the heat dissipation efficiency of the electronic device can be improved. The heat source of the electronic device can be a battery, a control chip (e.g. CPU), a memory (e.g. for example but not limited to SSD), a motherboard, a display card, a display panel, a flat light source of the electronic device, or any of other components, units, or modules, and this disclosure is not limited. In addition, the thermal conductive structure of the present disclosure can be applied to different product fields to meet the requirements of thin design.

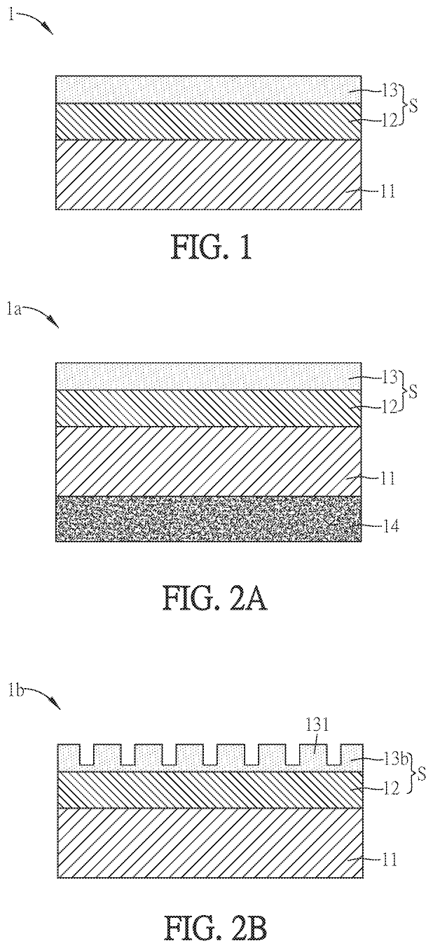

FIG. 1 is a schematic diagram showing a thermal conductive structure according to an embodiment of this disclosure. As shown in FIG. 1, the thermal conductive structure 1 of this embodiment comprises a thermal conductive metal layer 11 and a structural layer S.

The thermal conductive metal layer 11 comprises a material with high thermal conductive coefficient such as a metal plate, a metal foil, or a metal film, and the material thereof can be, for example but not limited to, copper, aluminum, copper alloy (an alloy containing copper and other metals), or aluminum alloy (an alloy containing aluminum and other metals), or a combination thereof. In this embodiment, for example, the thermal conductive metal layer 11 is an aluminum foil.

The structural layer S is disposed on the thermal conductive metal layer 11. The structural layer S can be a stacked structure formed by a graphene layer 12 and a ceramic material layer 13; or the structural layer S can be a graphene-mixed ceramic material layer. In this embodiment, for example, the structural layer S is a stacked structure formed by a graphene layer 12 and a ceramic material layer 13. In this embodiment, the graphene layer 12 is disposed between the ceramic material layer 13 and the thermal conductive metal layer 11. Herein, the graphene layer 12 comprises a plurality of graphene microchips. Since the graphene microchips have extremely high thermal conductivity (>3000 W/m-K), the thermal conductive structure 1 can have good thermal conductive effect. In some embodiments, the graphene microchips can be uniformly mixed within a solvent (and binder) to obtain a slurry, and then the slurry can be disposed on the thermal conductive layer 11 by, for example, coating or printing to form the graphene layer 12 (e.g. a graphene thermal film, GTF). The above-mentioned solvent can be, for example but not limited to, methyl ethyl ketone (MEK), water, acetone, ethyl acetate (EAC), methyl 3-methoxypropionate (MMP), toluene, alcohol, or a combination thereof, or any of other medium to high polar solvents. In addition, the coating process can be, for example but not limited to, a spray coating or a spin coating, and the printing process can be, for example but not limited to, an inkjet printing or a screen printing. In some embodiments, the content of the graphene microchips in the entire graphene layer 12 can be greater than 0 and be less than or equal to 15% (0<the content of graphene microchips<15%), such as 1.5%, 3.2%, 5%, 7.5%, 11%, 13%, or the like.

In this embodiment, the ceramic material layer 13 is disposed on a surface of the graphene layer 12 away from the thermal conductive metal layer 11. In some embodiments, the ceramic material layer 13 can be formed on the graphene layer 12 by coating or printing, thereby forming the structural layer S. The material of the ceramic material layer 13 can comprise, for example but not limited to, an adhesive material and a ceramic material with high thermal conductive coefficient, and the ceramic material is mixed in the adhesive material. The ceramic material can comprise, for example, boron nitride (BN), aluminum oxide (Al₂O₃), aluminum nitride (AlN), silicon carbide (SiC), or any combination thereof, or any of other ceramic material with high thermal conductive coefficient (K). In this embodiment, the material of the ceramic material layer 13 is, for example, a ceramic material comprising boron nitride (BN). To be noted, the graphene layer 12 has the electronic conductivity. Accordingly, compared with the conventional protective layer, which is made of polyimide (PI), the ceramic material layer 13 can not only provide the protection (wearing durability) and insulation properties, but also improve the thermal conductive effect. In other embodiments, the ceramic material layer 13 can be attached to the upper surface of the graphene layer 12 by, for example, a thermal conductive adhesive.

As mentioned above, in the thermal conductive structure 1 of this embodiment, the structural layer S is disposed on the thermal conductive metal layer 11, and the structural layer S is a stacked structure formed by a graphene layer 12 and a ceramic material layer 13. When the thermal conductive structure 1 is connected to the heat source of the electronic device, the heat energy generated by the heat source can be rapidly and effectively conducted to the outside, thereby improving the heat dissipation performance of the electronic device. Besides, compared with the conventional protective layer that is made of PI, the ceramic material layer 13 of this embodiment can provide the protection (wearing durability) and insulation effects, and can further improve the thermal conductive effect by the contained ceramic material. Moreover, the thermal conductive structure 1 of this embodiment can be applied to different product fields, thereby achieving the requirement of thin design of the electronic device.

In some embodiments, the thermal conductive structure can further comprise two release layers (not shown), which are disposed at two opposite sides of the thermal conductive structure (e.g. the upper side and the lower side of the thermal conductive structure 1 as shown in FIG. 1). Upon using the thermal conductive structure, the user can merely remove the two release layers so as to attach the thermal conductive structure to the heat source through the double-sided tape (e.g. a thermal conductive double-sided tape). The material of the thermal conductive double-sided tape can provide the adhesion function and assist to conduct the heat energy. In addition, the material of the release layers can be, for example but not limited to, paper, cloth, polyester (e.g. polyethylene terephthalate, PET), or a combination thereof, and this disclosure is not limited. To be noted, the aspect that the upper and lower sides of the thermal conductive structure are configured with corresponding release layers can also be applied to all of the following embodiments of the present disclosure.

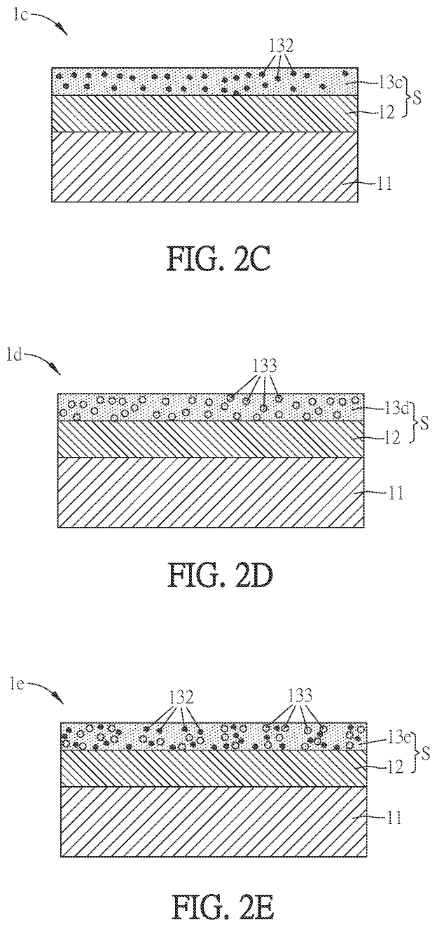

FIGS. 2A to 2G are schematic diagrams showing the thermal conductive structures according to different embodiments of this disclosure.

The configurations and connections of the components in the thermal conductive structure 1a of this embodiment as shown in FIG. 2A are mostly the same as those of the thermal conductive structure 1 of the above-mentioned embodiment. Different from the above embodiment, the thermal conductive structure 1a of this embodiment further comprises a double-sided adhesive layer 14 disposed at one side of the thermal conductive metal layer 11 away from the structural layer S. The double-sided adhesive layer 14 can be, for example, a thermal conductive double-sided tape. In this embodiment, the double-sided adhesive layer 14 is disposed on the lower surface of the thermal conductive metal layer 11 away from the graphene layer 12. Since the double-sided adhesive layer 14 is disposed between the thermal conductive metal layer 11 and the heat source, the thermal conductive structure 1a can be attached to the heat source for rapidly conducting and dissipating the heat energy generated by the heat source to the outside through the thermal conductive structure 1a. Of course, one side of the ceramic material layer 13 away from the heat source can also be configured with a heat dissipation structure (not shown) for speeding the heat dissipation.

The above-mentioned thermal conductive double-sided tape comprises an adhesive material and a thermal conductive material, and the thermal conductive material is mixed in the adhesive material. The thermal conductive double-sided tape can provide the adhesion function and assist to conduct the heat energy through the thermal conductive material. The thermal conductive material can comprise, for example, graphene, reduced graphene oxide, or ceramic material, or any combination thereof. The ceramic material can be a ceramic material with high thermal conductive coefficient (K) such as, for example but not limited to, boron nitride (BN), aluminum oxide (Al₂O₃), aluminum nitride (AlN), silicon carbide (SiC), or any combination thereof, and this disclosure is not limited. In addition, the adhesive material can be, for example but not limited to, a pressure sensitive adhesive (PSA), which is made of, for example, rubber, acrylic, or silicone, or a combination thereof. The chemical composition thereof can be rubber, acrylic, or silicone, or a combination thereof, and the disclosure is not limited. To be realized, the feature of utilizing the double-sided adhesive layer 14 to connect (the thermal conductive metal layer of) the thermal conductive structure and the heat source can also be applied to all of the following embodiments.

In addition, the configurations and connections of the components in the thermal conductive structure 1b of this embodiment as shown in FIG. 2B are mostly the same as those of the thermal conductive structure 1 of the above-mentioned embodiment. Different from the above embodiment, a surface of the ceramic material layer 13b of the thermal conductive structure 1b of this embodiment away from the thermal conductive metal layer 11 is configured with a plurality of microstructures 131, and the shape of the microstructures 131 can be, for example, columnar, spherical, pyramidal, trapezoidal, irregular shape, or any combination thereof. This disclosure is not limited thereto. In some embodiments, the microstructures 131 can be fabricated on the surface of the ceramic material layer 13b by, for example, screen printing, embossing printing, or other methods, so as to increase the heat dissipation area. This configuration can enhance the heat dissipation effect. The feature of forming a plurality of microstructures 131 on the surface of the ceramic material layer 13b can also be applied to other embodiments of this disclosure as shown in FIGS. 2C to 2E.

In addition, the configurations and connections of the components in the thermal conductive structure 1c of this embodiment as shown in FIG. 2C are mostly the same as those of the thermal conductive structure 1 of the above-mentioned embodiment. Different from the above embodiment, the ceramic material layer 13c of the thermal conductive structure 1c further comprises a filling material 132. The filling material 132 can be, for example, a ceramic material, and the shape thereof can be granular, flake, spherical, strip, nanotube, irregular, or any combination thereof, and this disclosure is not limited. Moreover, the particle size of the filling material 132 is between 0.5 μm and 10 μm. In some embodiments, the filling material 132 comprises, for example, aluminum oxide, aluminum nitride, silicon carbide, boron nitride, or any combination thereof. The configuration of the filling material 132 can increase the heat dissipation effect of the ceramic material layer 13c. The filling material 132 having a nanotube shape can be a boron nitride nanotube.

In addition, the configurations and connections of the components in the thermal conductive structure 1d of this embodiment as shown in FIG. 2D are mostly the same as those of the thermal conductive structure 1 of the above-mentioned embodiment. Different from the above embodiment, the ceramic material layer 13d of the thermal conductive structure 1d further comprises a plurality of pores 133. In some embodiments, a pore forming agent can be added in the manufacturing process of the ceramic material layer 13d, so that the ceramic material layer 13d can be formed with a plurality of pores 133 to increase the specific surface area and thus enhance the heat-radiation heat dissipation effect. In some embodiments, the pore forming agent is, for example, a ceramic pore forming agent.

In addition, the configurations and connections of the components in the thermal conductive structure 1e of this embodiment as shown in FIG. 2E are mostly the same as those of the thermal conductive structure 1 of the above-mentioned embodiment. Different from the above embodiment, the ceramic material layer 13e of the thermal conductive structure 1e comprises a filling material 132 and a plurality of pores 133.

In addition, the configurations and connections of the components in the thermal conductive structure if of this embodiment as shown in FIG. 2F are mostly the same as those of the thermal conductive structure 1 of the above-mentioned embodiment. Different from the above embodiment, the ceramic material layer 13 of the thermal conductive structure if is disposed between the graphene layer 12 and the thermal conductive metal layer 11. Moreover, the above-mentioned feature of adding the filling material in the ceramic material can also be applied to this embodiment.

In addition, the configurations and connections of the components in the thermal conductive structure 1g of this embodiment as shown in FIG. 2G are mostly the same as those of the thermal conductive structure 1 of the above-mentioned embodiment. Different from the above embodiment, the structural layer S of this embodiment is a graphene-mixed ceramic material layer 15. The material of the graphene-mixed ceramic material layer 15 comprises graphene and a ceramic material, wherein the ceramic material can be, for example but not limited to, boron nitride (BN), aluminum oxide (Al₂O₃), aluminum nitride (AlN), silicon carbide (SiC), or any combination thereof, or any of other ceramic material with high thermal conductive coefficient (K). In some embodiments, the mixing ratio of graphene and the ceramic material can be, for example, 1:9, 3:7, 5:5, or any other ratios, and this disclosure is not limited. In some embodiments, the graphene-mixed ceramic material layer 15 can further comprise the above-mentioned filling material. In addition, the feature of the above-mentioned microstructures can also be applied to the graphene-mixed ceramic material layer 15 of this embodiment.

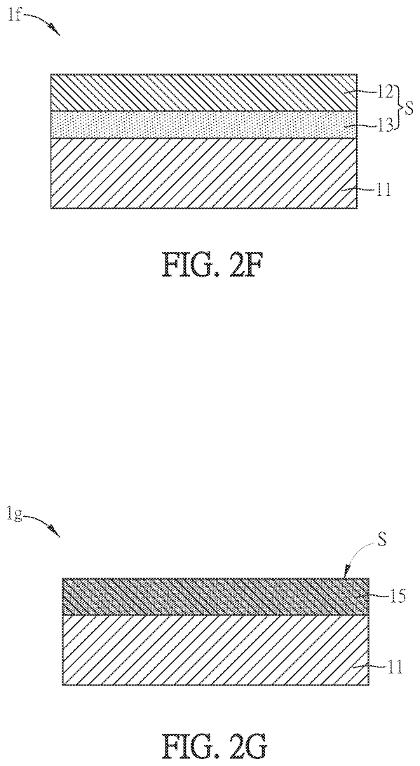

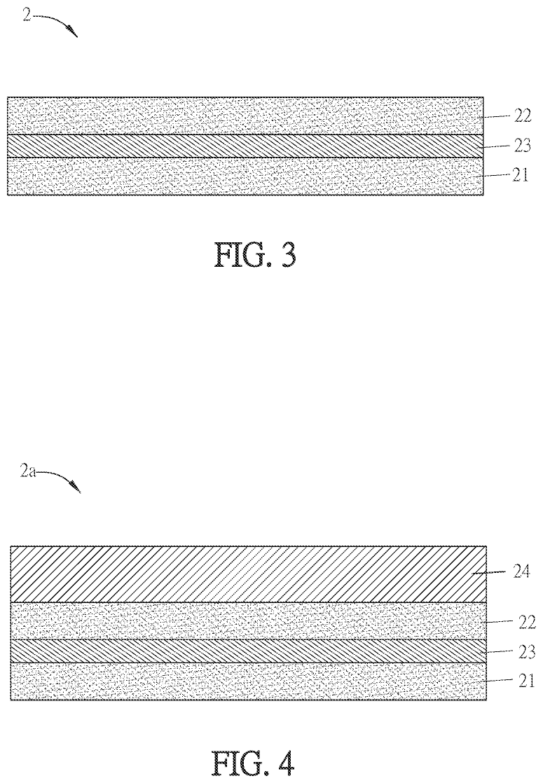

FIGS. 3 and 4 are schematic diagrams showing the electronic devices according to different embodiments of this disclosure. As shown in FIG. 3, this disclosure further provides an electronic device 2, which comprises a heat source 21 and a thermal conductive structure 22. The thermal conductive structure 22 is connected to the heat source 21. In some embodiments, the thermal conductive structure 22 is connected to the heat source 21 through a double-sided adhesive layer 23, such as a thermal conductive double-sided tape. In this embodiment, the thermal conductive structure 22 can be any of the above mentioned thermal conductive structure 1 and 1a to 1g, or their modifications. The specific technical content thereof can be referred to the above embodiments, so the detailed descriptions thereof will be omitted. To be understood, if the thermal conductive structure 22 further comprises the above-mentioned double-sided adhesive layer 14, the double-sided adhesive layer 23 is not needed.

The electronic device 2 or 2a can be, for example but not limited to, a flat display device or a flat light source, such as, for example but not limited to, a mobile phone, a laptop computer, a tablet computer, a TV, a display device, a backlight module, or a lighting module, or any of other flat electronic devices. The heat source can be a battery, a control chip (e.g. CPU), a driving chip, a memory (e.g. for example but not limited to SSD), a motherboard, a display card, a display panel, a flat light source of the electronic device, or any of other components or units capable of generating heat, and this disclosure is not limited. In some embodiments, when the electronic device 2 is a flat display device, such as, for example but not limited to, an LED display device, an OLED display device, or an LCD, the heat source 21 can be a display panel with a display surface, and the thermal conductive structure 22 can be directly or indirectly (e.g. through a thermal conductive double-sided tape) attached to the surface opposite to the display surface, thereby assisting the heat conduction and heat dissipation, and thus improving the heat dissipation performance of the flat display device. In other embodiments, when the electronic device 2 is a flat light source, such as, for example but not limited to, a backlight module, an LED lighting module, or an OLED lighting module, the heat source 21 can be a light-emitting unit with a light outputting surface. The thermal conductive structure 22 can be directly or indirectly (e.g. through the adhesive) attached to the surface opposite to the light outputting surface, thereby assisting the heat conduction and heat dissipation, and thus improving the heat dissipation performance of the flat light source.

In addition, as shown in FIG. 4, the electronic device 2a of this embodiment further comprises a heat dissipation structure 24, which is disposed at one side of the thermal conductive structure 22 away from the heat source 21. Accordingly, in the electronic device 2a, the heat dissipation structure 24 can be connected to the heat source 21 through the thermal conductive structure 22, so that the heat energy generated by the heat source 21 can be rapidly transmitted to the heat dissipation structure 24 through the thermal conductive structure 22. Then, the heat energy generated by the electronic device 2a can be dissipated to the outside through the heat dissipation structure 24, thereby improving the heat dissipation effect. In some embodiments, the heat dissipation structure 24 can be, for example, a heat-dissipation film such as, for example but not limited to, a graphene thermal film (GTF). In addition, the heat dissipation structure 24 can be any conventional heat dissipation device or structure such as the fan, fins, heat dissipation paste, heat-dissipation plate, heat sink, . . . , or any of other types of heat dissipation elements, heat dissipation units or heat dissipation devices, or combinations thereof, and this disclosure is not limited. In some embodiments, the heat dissipation structure 24 and the thermal conductive structure 22 can be connected through, for example, a thermal conductive double-sided tape.

In addition, several comparative experiments are performed, wherein the control group 1 utilizes an aluminum metal sheet layer, the control group 2 utilizes an aluminum metal sheet layer and a graphene layer, and three experimental groups utilize the thermal conductive structure 1, the thermal conductive structure 1f, and the thermal conductive structure 1g of the present invention, respectively. Under the condition of the same heat source, the temperature of the surface of the thermal conductive structure 1 away from the heat source is about 12.5° C. lower than that of the control group 1; the temperature of the surface of the thermal conductive structure if away from the heat source is about 13.21° C. lower than that of the control group 1; the highest temperature of the surface of the thermal conductive structure 1g away from the heat source is about 10.32° C. lower than that of the control group 1; the temperature of the surface of the thermal conductive structure 1 away from the heat source is about 5.06° C. lower than that of the control group 2; the temperature of the surface of the thermal conductive structure if away from the heat source is about 5.77° C. lower than that of the control group 2; and the highest temperature of the surface of the thermal conductive structure 1g away from the heat source is about 2.88° C. lower than that of the control group 2. These experimental results prove that the structural design of the present disclosure, which disposes a structural layer S on a thermal conductive metal layer 11 (wherein the structural layer S can be a stacked structure formed by a graphene layer 12 and a ceramic material layer 13, or a graphene-mixed ceramic material layer 15), can exactly and effectively conduct the heat energy generated by the heat source to the outside, thereby improving the heat dissipation performance.

In summary, in the thermal conductive structure of this disclosure, the structural layer is disposed on the thermal conductive metal layer, and the structural layer is a stacked structure formed by a graphene layer and a ceramic material layer, or a graphene-mixed ceramic material layer. When the thermal conductive structure is connected to the heat source of the electronic device, the heat energy generated by the heat source can be rapidly and effectively conducted to the outside, thereby improving the heat dissipation performance of the electronic device. Moreover, the thermal conductive structure of this disclosure can be applied to different product fields, thereby achieving the requirement of thin design of the electronic device. Besides, compared with the conventional protective layer that is made of PI, the ceramic material layer of one embodiment of this disclosure can provide the protection and insulation effects, and can further improve the thermal conductive effect.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A thermal conductive structure, comprising:
a thermal conductive metal layer; and
a structural layer disposed on the thermal conductive metal layer;
wherein the structural layer is a stacked structure formed by a graphene layer and a ceramic material layer; or the structural layer is a graphene-mixed ceramic material layer.

2. The thermal conductive structure of claim 1, wherein the thermal conductive metal layer comprises copper, aluminum, copper alloy, or aluminum alloy.

3. The thermal conductive structure of claim 1, wherein a material of the ceramic material layer comprises boron nitride, aluminum oxide, aluminum nitride, silicon carbide, or any combination thereof.

4. The thermal conductive structure of claim 1, wherein a material of the graphene-mixed ceramic material layer comprises graphene and a ceramic material, and the ceramic material comprises boron nitride, aluminum oxide, aluminum nitride, silicon carbide, or any combination thereof.

5. The thermal conductive structure of claim 1, wherein the ceramic material layer is disposed between the graphene layer and the thermal conductive metal layer.

6. The thermal conductive structure of claim 1, wherein the graphene layer is disposed between the ceramic material layer and the thermal conductive metal layer.

7. The thermal conductive structure of claim 6, wherein a surface of the ceramic material layer away from the thermal conductive metal layer is configured with a plurality of microstructures, and a shape of the microstructures is columnar, spherical, pyramidal, trapezoidal, irregular shape, or any combination thereof.

8. The thermal conductive structure of claim 6, wherein the ceramic material layer further comprises a filling material and/or a plurality of pores.

9. The thermal conductive structure of claim 1, wherein a surface of the graphene-mixed ceramic material layer away from the thermal conductive metal layer is configured with a plurality of microstructures, and a shape of the microstructures is columnar, spherical, pyramidal, trapezoidal, irregular shape, or any combination thereof.

10. The thermal conductive structure of claim 1, wherein the graphene-mixed ceramic material layer further comprises a filling material.

11. The thermal conductive structure of claim 8, wherein the filling material comprises aluminum oxide, aluminum nitride, silicon carbide, boron nitride, or any combination thereof.

12. The thermal conductive structure of claim 10, wherein the filling material comprises aluminum oxide, aluminum nitride, silicon carbide, boron nitride, or any combination thereof.

13. The thermal conductive structure of claim 8, wherein a shape of the filling material comprises granular, flake, spherical, strip, nanotube, irregular, or any combination thereof.

14. The thermal conductive structure of claim 10, wherein a shape of the filling material comprises granular, flake, spherical, strip, nanotube, irregular, or any combination thereof.

15. The thermal conductive structure of claim 1, further comprising:
a double-sided adhesive layer disposed at one side of the thermal conductive metal layer away from the structural layer.

16. The thermal conductive structure of claim 15, wherein the double-sided adhesive layer is a thermal conductive double-sided tape.

17. An electronic device, comprising:
a heat source; and
a thermal conductive structure of claim 1, wherein the thermal conductive structure is connected to the heat source.

18. The electronic device of claim 17, further comprising:
a heat-dissipation structure disposed at one side of the thermal conductive structure away from the heat source.

19. The electronic device of claim 17, wherein the thermal conductive structure further comprises:
a double-sided adhesive layer disposed at one side of the thermal conductive metal layer away from the structural layer.

20. The electronic device of claim 17, wherein the graphene-mixed ceramic material layer further comprises a filling material.
